(19) United States
(12) Patent Application Publication
(10) Pub. No.: US 2013/0183824 A1
(43) Pub. Date: Jul. 18, 2013

(54) METHOD OF FABRICATING A SEMICONDUCTOR DEVICE

(71) Applicant: SAMSUNG ELECTRONICS CO., LTD., Suwon-si (KR)

(72) Inventors: Byoungho KWON, Hwaseong-si (KR); Kuntack LEE, Hwaseong-si (KR); Yongsun KO, Suwon-si (KR); Hongjin KIM, Seoul (KR); Sangwon BAE, Namdong-gu (KR); Sigyung AHN, Seongnam-si (KR); Jun-Youl YANG, Seoul (KR); Sol HAN, Yangpyeong-gun (KR); Bo yun KIM, Hwaseong-si (KR); Myung-Ki HONG, Seoul (KR)

(73) Assignee: SAMSUNG ELECTRONICS CO., LTD., Suwon-si (KR)

(21) Appl. No.: 13/733,506

(22) Filed: Jan. 3, 2013

(30) Foreign Application Priority Data
Jan. 18, 2012 (KR) 10-2012-0005899

(51) Int. Cl. H01L 21/768

(52) U.S. Cl. CPC H01L 21/76841
USPC 438/653

(57) ABSTRACT

A method of fabricating a semiconductor device includes forming a first layer including a first metal, forming a second layer including a second metal, the second layer being adjacent to the first layer, polishing top surfaces of the first and second layers, and cleaning the first and second layers using a cleaning solution. The cleaning solution may include an etching solution etching the first and second layers and an inhibitor suppressing the second layer from being over etched.

### CROSS-REFERENCE TO RELATED APPLICATION

This U.S. non-provisional patent application claims priority under 35 U.S.C. §119 to Korean Patent Application No. 10-2012-0005899, filed on Jan. 18, 2012, in the Korean Intellectual Property Office, the entire contents of which are hereby incorporated by reference.

### BACKGROUND

1. Field

Embodiments relate generally to a method of fabricating a semiconductor device, and more particularly, to a method of fabricating a semiconductor device with metal patterns.

2. Description of the Related Art

With increasing integration density of semiconductor devices, an interval between metal patterns has gradually decreased. For example, intervals between metal lines, between contacts, and between plugs have been reduced.

### SUMMARY

Embodiments are directed to a method of fabricating a semiconductor device including forming a first layer including a first metal, forming a second layer including a second metal, the second layer being adjacent to the first layer, polishing top surfaces of the first and second layers, and cleaning the first and second layers using a cleaning solution. The cleaning solution may include an etching solution etching the first and second layers and an inhibitor suppressing the second layer from being over etched.

The etching solution may include at least one of sulfuric acid, phosphoric acid, or hydrogen peroxide. The inhibitor may include a nitrogen compound.

The nitrogen compound may include at least one of ammonium phosphate, ammonium sulfate, ammonium nitrate, ammonium borate, ammonium persulfate, ammonium citrate, ammonium oxalate, ammonium formate, ammonium carbonate, 2-(N,N-diethylamino) ethyl methacrylate, 2-(N,N-dimethylamino) ethyl acrylate, 2-acryloxyethyltrimethylammonium chloride, 2-methacryloxyethyltrimethylammonium chloride, 4,4′-diamino-3,3′-dinitrodiphenyl ether, 4-vinylpyridine, chitin, chitosan, diallyldimethylammonium chloride, methacryloylcholine methyl sulfate N-dodecylmethacrylamide, poly(2-dimethylaminoethyl methacrylate), poly(2-methacryloxyethyltrimethylammonium bromide), poly(2-vinyl-1-methylpyridinium bromide), poly(2-vinylpyridine N-oxide), poly(2-vinylpyridine), poly(3-chloro-2-hydroxypropyl-2-methacryloxyethyldimethyl ammonium chloride), poly(4-aminostyrene), poly(4-vinylpyridine N-oxide), poly(4-vinylpyridine), poly(allylamine), amine terminated poly(allylamine hydrochloride), poly(butadiene/acrylonitrile), poly(diallyldimethylammonium chloride), poly(ethylene glycol) bis 2-aminoethyl), poly(L-lysine hydrobromide), poly(N-methylvinylamine), poly(N-vinylpyrrolidone), poly(N-vinylpyrrolidone/2-dimethylaminoethyl methacrylate) dimethyl sulfate quaternary, poly(vinylamine) hydrochloride, polyaniline, or polyethylenimine.

The method may further include physically cleaning the first and second layers having the polished top surfaces.

The physical cleaning may be performed using at least one of a spraying method, an ultrasonic method, or a scrubbing method, in which at least one of diluted hydrofluoric acid, diluted ammonia, or deionized water may be used.

The cleaning of the first and second layers using the cleaning solution may include spraying the cleaning solution.

The cleaning of the first and second layers using the cleaning solution may further include physically cleaning the first and second layers using an ultrasonic wave, the using of the ultrasonic wave being executed simultaneously with the using of the cleaning solution.

The first layer may include a titanium/titanium nitride layer. The second layer may include a tungsten layer. The etching solution may include sulfuric acid and hydrogen peroxide. The inhibitor may include at least one of ammonium phosphate, ammonium sulfate, ammonium nitrate, ammonium borate, ammonium persulfate, ammonium citrate, ammonium oxalate, ammonium formate, or ammonium carbonate.

The forming of the first and second layers may include forming a recess in a lower structure, forming the first layer on the lower structure in a conformal manner, and forming the second layer to fill the recess formed with the first layer.

The polishing of the top surfaces of the first and second layers may expose a top surface of the lower structure.

The cleaning of the first and second layers using the cleaning solution may remove a polishing by-products produced during the forming of the recess and the polishing of the first and second layers.

The cleaning solution may provide an etch rate of the first layer that is equivalent to or higher than an etch rate of the second layer.

The cleaning solution may provide a ratio of an etch rate of the first layer to an etch rate of the second layer that is from about 1 to about 20.

Embodiments are also directed to a method of fabricating a semiconductor device, the method including conformally forming a first layer including a first metal on a lower structure, the lower structure including a recess, forming a second layer including a second metal on the first layer and filling the recess, the second metal being different from the first metal, performing polishing to form a resultant surface structure including an exposed top surface of the lower structure and exposed top surfaces of the first layer and the second layer in the recess, and treating the resultant surface structure with a solution that etches the first layer and the second layers, the solution including an inhibitor that prevents the second layer from being over etched.

The solution may include at least one of sulfuric acid, phosphoric acid, or hydrogen peroxide. The inhibitor may include at least one of ammonium phosphate, ammonium sulfate, ammonium nitrate, ammonium borate, ammonium persulfate, ammonium citrate, ammonium oxalate, ammonium formate, ammonium carbonate, 2-(N,N-diethylamino) ethyl methacrylate, 2-(N,N-dimethylamino) ethyl acrylate, 2-acryloxyethyltrimethylammonium chloride, 2-methacryloxyethyltrimethylammonium chloride, 4,4′-diamino-3,3′-dinitrodiphenyl ether, 4-vinylpyridine, chitin, chitosan, diallyldimethylammonium chloride, methacryloylcholine methyl sulfate N-dodecylmethacrylamide, poly(2-dimethylaminoethyl methacrylate), poly(2-methacryloxyethyltrimethylammonium bromide), poly(2-vinyl-1-methylpyridinium bromide), poly(2-vinylpyridine N-oxide), poly(2-vinylpyridine), poly(3-chloro-2-hydroxypropyl-2-methacryloxyethyldimethyl ammonium chloride), poly(4-aminostyrene), poly(4-vinylpyridine N-oxide), poly(4-vinylpyridine), poly(allylamine), amine terminated poly(allylamine hydrochloride), poly(butadiene/acrylonitrile), poly(diallyldimethylammonium chloride), poly(ethylene glycol) bis 2-aminoethyl), poly(L-lysine hydrobromide), poly(N-methylvinylamine), poly(N-vinylpyrrolidone), poly(N-vinylpyrrolidone/2-dimethylaminoethyl methacrylate) dimethyl sulfate quaternary, poly(vinylamine) hydrochloride, polyaniline, or polyethylenimine.

The first layer may include titanium or titanium nitride as the first metal. The second layer may include tungsten as the second metal. The solution may include sulfuric acid and hydrogen peroxide. The inhibitor may include at least one of ammonium phosphate, ammonium sulfate, ammonium nitrate, ammonium borate, ammonium persulfate, ammonium citrate, ammonium oxalate, ammonium formate, or ammonium carbonate.

The method may further include physically cleaning the resultant surface structure using at least one of a spraying method, an ultrasonic method, or a scrubbing method. Physically cleaning of the resultant surface structure may be carried out using at least one of diluted hydrofluoric acid, diluted ammonia, or deionized water. Physically cleaning the resultant surface structure may be carried out in at least one of before, during, or after the cleaning of the resultant structure using the cleaning solution.

The solution may provide an etch rate of the first layer that is equivalent to or higher than an etch rate of the second layer.

The solution may provide a ratio of an etch rate of the first layer to an etch rate of the second layer ranges from about 1 to about 20.

### BRIEF DESCRIPTION OF THE DRAWINGS

Features will become apparent to those of skill in the art by describing in detail exemplary embodiments with reference to the attached drawings in which:

FIGS. 1 through 5 are sectional views illustrating stages of a method of fabricating a semiconductor device according to example embodiments.

FIG. 6 illustrates a flow chart illustrating a cleaning process of FIG. 5.

FIG. 7 illustrates a flow chart illustrating a method of fabricating a semiconductor device according to other embodiments.

FIGS. 8A and 8B schematically depict images illustrating yields of wafers in which semiconductor devices were fabricated by a method according to example embodiments.

FIGS. 9A and 9B schematically depict images illustrating yields of wafers, in which semiconductor devices were fabricated by a conventional method.

FIG. 10 is a graph illustrating a relationship between an etching amount of a tungsten layer and a size of void or seam formed in the tungsten layer.

FIG. 11A is a block diagram illustrating a memory card including a semiconductor device according to the example embodiments.

FIG. 11B is a block diagram illustrating an information processing system including a semiconductor device according to the example embodiments.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments will now be described more fully with reference to the accompanying drawings, in which example embodiments are shown. Example embodiments may, however, be embodied in many different forms and should not be construed as being limited to the embodiments set forth herein; rather, these embodiments are provided so that this disclosure will be thorough and complete, and will fully convey the concept of example embodiments to those of ordinary skill in the art.

It is to be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It is to be understood that, although the terms “first”, “second”, etc. may be used herein to describe various elements, components, regions, layers and/or sections, these elements, components, regions, layers and/or sections should not be limited by these teams. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It is to be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It is to be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It is to be further understood that terms, such as those defined in commonly-used dictionaries, should be interpreted as having a meaning that is consistent with their meaning in the context of the relevant art and will not be interpreted in an idealized or overly formal sense unless expressly so defined herein.

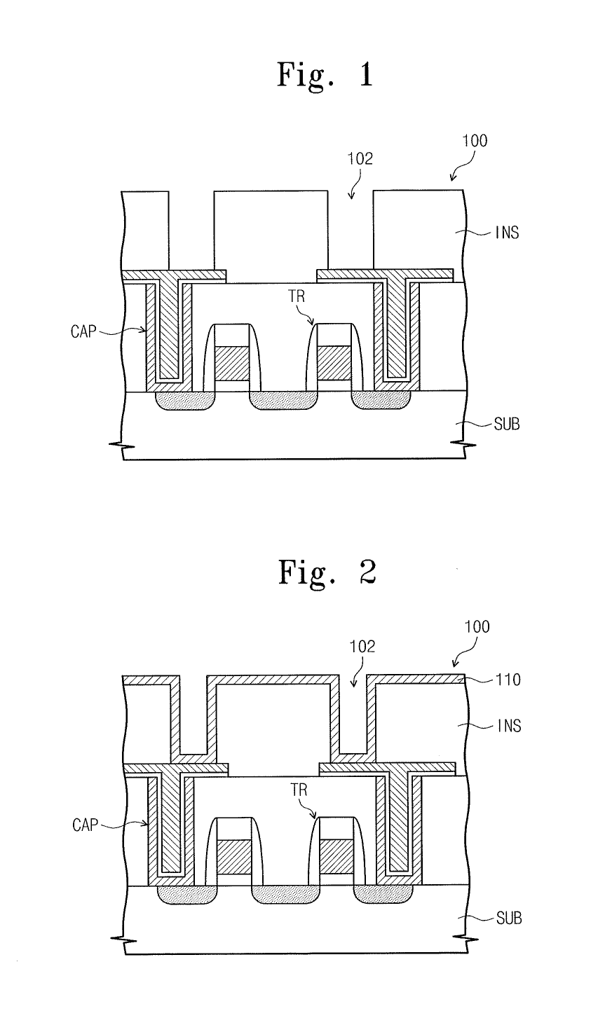

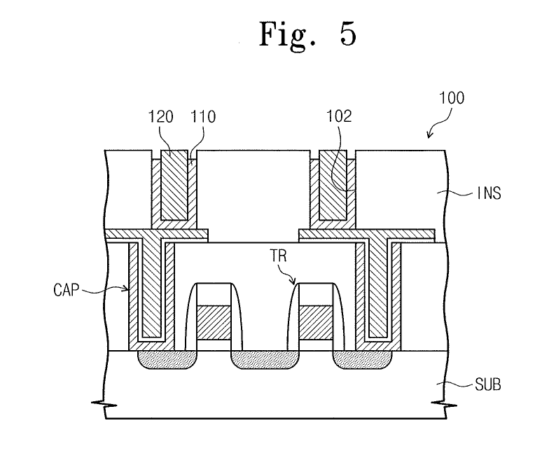

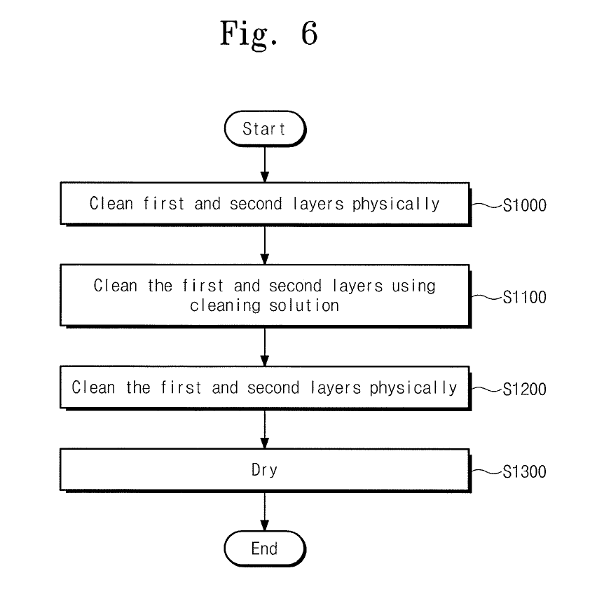

FIGS. 1 through 5 are sectional views illustrating stages of a method of fabricating a semiconductor device according to example embodiments. FIG. 6 is a flow chart illustrating a cleaning process of FIG. 5.

Referring to FIG. 1, a recess 102 may be formed in a lower structure 100.

According to some aspects, the lower structure 100 may be a substrate SUB. According to other aspects, the lower structure 100 may include a pattern structure (such as, a transistor TR, a capacitor CAP, or metal patterns) provided on the substrate SUB and an insulating layer INS covering the pattern structure.

The recess 102 may be shaped like a line extending along a specific direction or like a hole, which may expose a top surface of the pattern structure of the lower structure 100 through the insulating layer INS.

Referring to FIG. 2, a first layer 110 may be formed to cover conformally the lower structure 100 provided with the recess 102. The first layer 110 may be formed not to fill the recess 102.

According to example embodiment, the first layer 110 may include a first metal. For example, the first layer 110 may include a metal or a metal compound. For example, the first layer 110 may include at least one selected from the group of titanium (Ti), tantalum (Ta), rubidium (Rb), titanium nitride (TiN), and tantalum nitride (TaN).

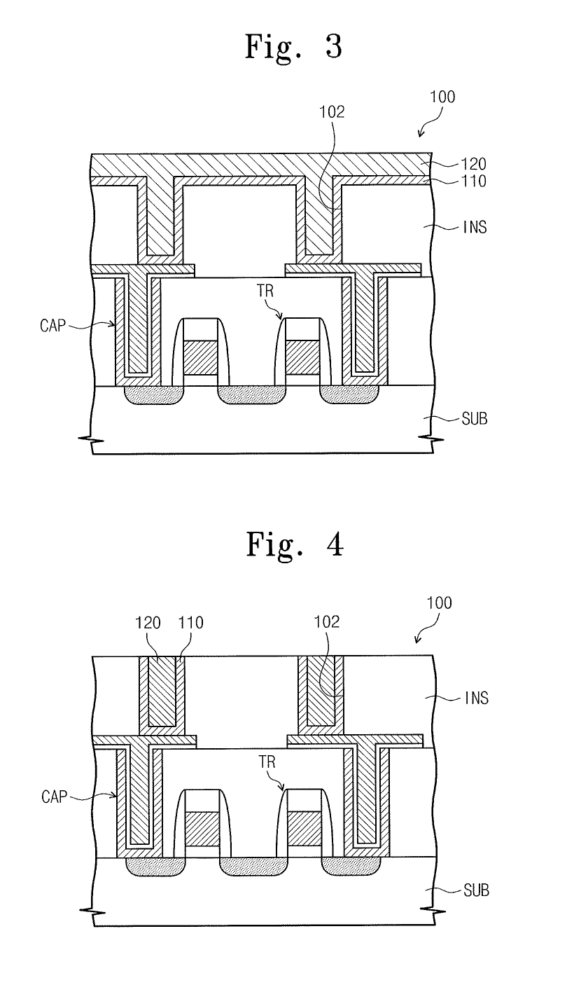

Referring to FIG. 3, a second layer 120 may be formed on the lower structure 100 to fill completely the recess 102 provided with the first layer 110.

In example embodiments, the second layer 120 may include a second metal. For example, the second layer 120 may include at least one selected from the group of tungsten (W), aluminum (Al), and copper (Cu).

Referring to FIG. 4, top surfaces of the first and second layers 110 and 120 may be polished to expose the top surface of the lower structure 100. The polishing of the first and second layers 110 and 120 may be performed using a chemical mechanical polishing (CMP) process.

Hereinafter, it will be briefly described how to polish the first and second layers 110 and 120 using the CMP process. For example, the top surfaces of the first and second layers 110 and 120 may be polished mechanically using a pushing and rotating polishing pad and may be polished chemically using a polishing compound supplied thereon. The CMP process may be terminated at the time when the top surface of the lower structure 100 is exposed.

During the CMP process, the first and second metals may partially drift away from the first and second layers 110 and 120, respectively, thereby serving as factors potentially causing a process failure in a subsequent process. In addition, the drifted portions of the first and second metals and the polished lower structure 100 may chemically react with the polishing compound to produce a polishing by-product, which may serve as another factor potentially causing a process failure.

Referring to FIGS. 5 and 6, a cleaning process may be performed to remove the drifted portions and residues of the first metal and second metals after the CMP process.

According to example embodiments, a cleaning solution supplied in the cleaning process may include an etching solution etching the first and second layers 110 and 120 and an inhibitor suppressing the second layer 120 from being over etched.

The etching solution may include at least one selected from the group of sulfuric acid (H₂SO₄), phosphoric acid (H₃PO₄), and hydrogen peroxide (H₂O₂). The etching solution may be selected to etch the first metal of the first layer 110 and the second metal of the second layer 120. According to some aspects, the etching solution may be selected to etch the lower structure 100.

The inhibitor may include a material capable of selectively suppressing the second metal from being etched by the etching solution. In example embodiments, the inhibitor may include a nitrogen compound. For example, the nitrogen compound may include at least one of ammonium phosphate, ammonium sulfate, ammonium nitrate, ammonium borate, ammonium persulfate, ammonium citrate, ammonium oxalate, ammonium formate, ammonium carbonate, 2-(N,N-diethylamino) ethyl methacrylate, 2-(N,N-dimethylamino) ethyl acrylate, 2-acryloxyethyltrimethyl ammonium chloride, 2-methacryloxyethyltrimethylammonium chloride, 4,4′-diamino-3,3′-dinitrodiphenyl ether, 4-vinylpyridine, chitin, chitosan, diallyldimethylammonium chloride, methacryloylcholine methyl sulfate, N-dodecylmethacrylamide, poly(2-dimethylaminoethyl methacrylate), poly(2-methacryloxyethyltrimethylammonium bromide), poly(2-vinyl-1-methylpyridinium bromide), poly(2-vinylpyridine N-oxide), poly(2-vinylpyridine), poly(3-chloro-2-hydroxypropyl-2-methacryloxyethyldimethyl ammonium chloride), poly(4-aminostyrene), poly(4-vinylpyridine N-oxide), poly(4-vinylpyridine), poly(allylamine), poly(allylamine hydrochloride), amine terminated poly(butadiene/acrylonitrile), poly(diallyldimethylammonium chloride), poly(ethylene glycol) bis 2-aminoethyl), poly(L-lysine hydrobromide), poly(N-methylvinylamine), poly(N-vinylpyrrolidone), poly(N-vinylpyrrolidone/2-dimethylaminoethyl methacrylate) dimethyl sulfate quaternary, poly(vinylamine) hydrochloride, polyaniline, or polyethylenimine. The cleaning process may be performed using one or a combination of materials enumerated above for the nitrogen compound.

As the result of the cleaning process, the drifted portions of the first metal and second metals and the polishing by-products may be removed from the first and second layers 110 and 120.

According to some aspects, the top surfaces of the first and second layers 110 and 120 may be etched by the cleaning solution during the cleaning process. In example embodiments, the first and second layers 110 and 120 may have the same etch rate to the etching solution to be used in the cleaning solution, but the first layer 110 may be etched faster than the second layer 120, due to the presence of the inhibitor suppressing the second layer 120 from being etched. As a result, the top surface of the first layer 110 may be substantially lower than that of the second layer 120. In other embodiments, the first layer 110 may be etched faster than the second layer 120, when the first layer 110 has a faster etch rate than the second layer 120 with respect to the etching solution to be used in the cleaning solution. In still other embodiments, the etching of the first layer 110 and the second layer 120 may be performed in the substantially same manner, when the first layer 110 may be smaller than the second layer 120 in terms of an etch rate to the etching solution to be used in the cleaning solution.

In example embodiments, the use of the cleaning solution may allow the first layer 110 to have an etch rate substantially equivalent to or greater than that of the second layer 120. For example, in the cleaning process, a ratio in etch rate of the first layer 110 to the second layer 120 may range from about 1 to about 100. In other implementations, a ratio in etch rate of the first layer 110 to the second layer 120 may range from about 1 to about 20.

In example embodiments, the first layer 110 may serve as a barrier layer, while the second layer 120 may serve as a plug, a contact, and/or a line, which may be electrically connected to the lower structure 100.

According to example embodiments, as described above, the top surfaces of the layers including different metals from each other may be polished and cleaned to remove the residues and the polishing by-products of the metals. As a result, it may be possible to prevent a process failure, which may be caused by the residues and the polishing by-products of the metals.

In example embodiments, the cleaning solution may be sprayed onto the polished top surfaces of the first and second layers 110 and 120 (in S1100). During the spraying of the cleaning solution, the first and second metals and the polishing by-product, which may be weakly attached to the first and second layers 110 and 120, may be detached from the first and second layers 110 and 120 by a mechanical energy of the sprayed cleaning solution. In addition, the drifted portions of the first metal and second metals and the polishing by-product may be chemically removed by the cleaning solution.

In other embodiments, before the cleaning process of the first and second layers 110 and 120 using the cleaning solution, a physical cleaning process may be further performed to the polished first and second layers 110 and 120 (in S1000). The physical cleaning process in S1000 may be performed by at least one of a spraying method, an ultrasonic method, and a scrubbing method, in which at least one of diluted hydrofluoric acid (HF), diluted ammonia, or deionized water is used. The use of the deionized water may help prevent static electricity from occurring.

In still other embodiments, after the cleaning process of the first and second layers 110 and 120 using the cleaning solution, a physical cleaning process may be further performed to the polished first and second layers 110 and 120 (in S1200). The physical cleaning process in S1200 may be performed by at least one of a spraying method, an ultrasonic method, and a scrubbing method, in which at least one of diluted hydrofluoric acid (HF), diluted ammonia, or deionized water is used.

In even other embodiments, before and after the cleaning process of the first and second layers 110 and 120 using the cleaning solution, a physical cleaning process may be further performed to the polished first and second layers 110 and 120 (in S1000 and S1200). The physical cleaning process in S1000 and S1200 may be performed by at least one of a spraying method, an ultrasonic method, and a scrubbing method, in which at least one of diluted hydrofluoric acid (HF), diluted ammonia, or deionized water is used.

After the cleaning process, the first and second layers 110 and 120 may be dried (in S1300) for a subsequent process.

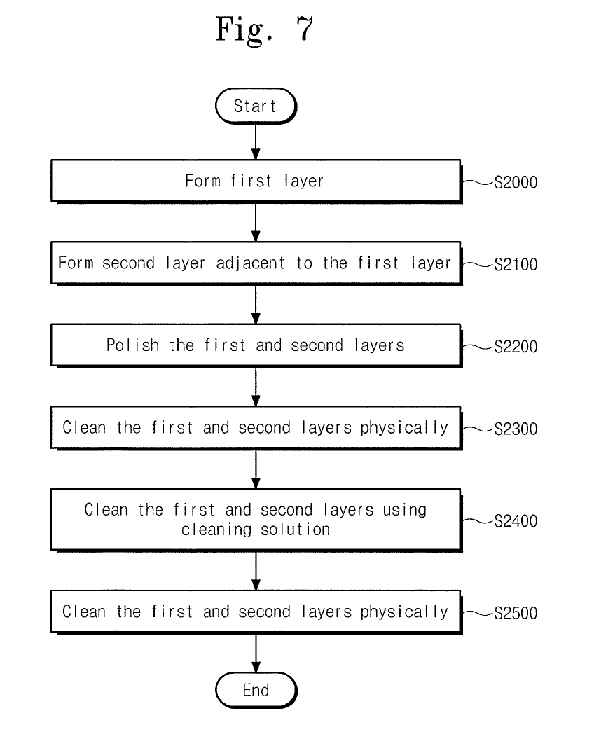

FIG. 7 is a flow chart illustrating a method of fabricating a semiconductor device according to other embodiments.

Referring to FIG. 7, a first layer may be formed to include a first metal (in S2000). In example embodiments, the first layer may include a metal or a metal compound. For example, the first layer may include at least one selected from the group of titanium (Ti), tantalum (Ta), rubidium (Rb), titanium nitride (TiN), and tantalum nitride (TaN).

A second layer may be formed adjacent to the first layer to include a second metal (in S2100). In example embodiments, the second layer may include a metal. For example, the second layer may include at least one selected from the group of tungsten (W), aluminum (Al), and copper (Cu).

Top surfaces of the first and second layers may be polished using a CMP process (in S2200). During the CMP process, the first and second metals may partially drift away from the first and second layers, respectively, thereby serving as factors potentially causing a process failure in a subsequent process. In addition, the drifted portions of the first and second metals may chemically react with the polishing compound to produce a polishing by-product.

A cleaning process may be performed to the polished first and second layers to remove the drifted portions of the first metal and second metals (in S2400).

In example embodiments, a cleaning solution supplied in the cleaning process may include an etching solution etching the first and second layers and an inhibitor suppressing the second layer from being over etched.

The etching solution may include at least one selected from the group of sulfuric acid (H₂SO₄), phosphoric acid (H₃PO₄), and hydrogen peroxide (H₂O₂). The etching solution may be selected to etch the first metal of the first layer and the second metal of the second layer.

The inhibitor may include a nitrogen compound. For example, the nitrogen compound may include at least one of ammonium phosphate, ammonium sulfate, ammonium nitrate, ammonium borate, ammonium persulfate, ammonium citrate, ammonium oxalate, ammonium formate, ammonium carbonate, 2-(N,N-diethylamino) ethyl methacrylate, 2-(N,N-dimethylamino) ethyl acrylate, 2-acryloxyethyltrimethyl ammonium chloride, 2-methacryloxyethyltrimethylammonium chloride, 4,4′-diamino-3,3′-dinitrodiphenyl ether, 4-vinylpyridine, chitin, chitosan, diallyldimethylammonium chloride, methacryloylcholine methyl sulfate, N-dodecylmethacrylamide, poly(2-dimethylaminoethyl methacrylate), poly(2-methacryloxyethyltrimethylammonium bromide), poly(2-vinyl-1-methylpyridinium bromide), poly(2-vinylpyridine N-oxide), poly(2-vinylpyridine), poly(3-chloro-2-hydroxypropyl-2-methacryloxyethyldimethyl ammonium chloride), poly(4-aminostyrene), poly(4-vinylpyridine N-oxide), poly(4-vinylpyridine), poly(allylamine), poly(allylamine hydrochloride), amine terminated poly(butadiene/acrylonitrile), poly(diallyldimethylammonium chloride), poly(ethylene glycol) bis 2-aminoethyl), poly(L-lysine hydrobromide), poly(N-methylvinylamine), poly(N-vinylpyrrolidone), poly(N-vinylpyrrolidone/2-dimethylaminoethyl methacrylate) dimethyl sulfate quaternary, poly(vinylamine) hydrochloride, polyaniline, or polyethylenimine. The cleaning process may be performed using one or a combination of materials enumerated above for the nitrogen compound.

As the result of the cleaning process, the drifted portions of the first metal and second metals and the polishing by-products may be removed from the first and second layers.

According to some aspects, the top surfaces of the first and second layers may be etched by the cleaning solution during the cleaning process. In example embodiments, the first and second layers may have the same etch rate to the etching solution to be used in the cleaning solution, but the first layer may be etched faster than the second layer, due to the presence of the inhibitor suppressing the second layer from being etched. As a result, the top surface of the first layer may be substantially lower than that of the second layer. In other embodiments, the first layer may be etched faster than the second layer, when the first layer has a faster etch rate than the second layer with respect to the etching solution to be used in the cleaning solution. In still other embodiments, the etching of the first layer and the second layer may be performed in the substantially same manner, when the first layer may be smaller than the second layer in terms of an etch rate to the etching solution to be used in the cleaning solution.

In example embodiments, the use of the cleaning solution may allow the first layer to have an etch rate substantially equivalent to or greater than that of the second layer. For example, in the cleaning process, a ratio in etch rate of the first layer to the second layer may range from about 1 to about 100. Alternatively, a ratio in etch rate of the first layer to the second layer may range from about 1 to about 20.

In example embodiments, the cleaning process may include spraying the cleaning solution. In other example embodiments, a physical cleaning process may be further performed before the cleaning process using the cleaning solution (in S2300). In still other example embodiments, a physical cleaning process may be further performed after the cleaning process using the cleaning solution (in S2500). In even other example embodiments, a physical cleaning process may be further performed before and after the cleaning process using the cleaning solution (in S2300 and S2500).

After the cleaning process, the first and second layers may be dried for a subsequent process.

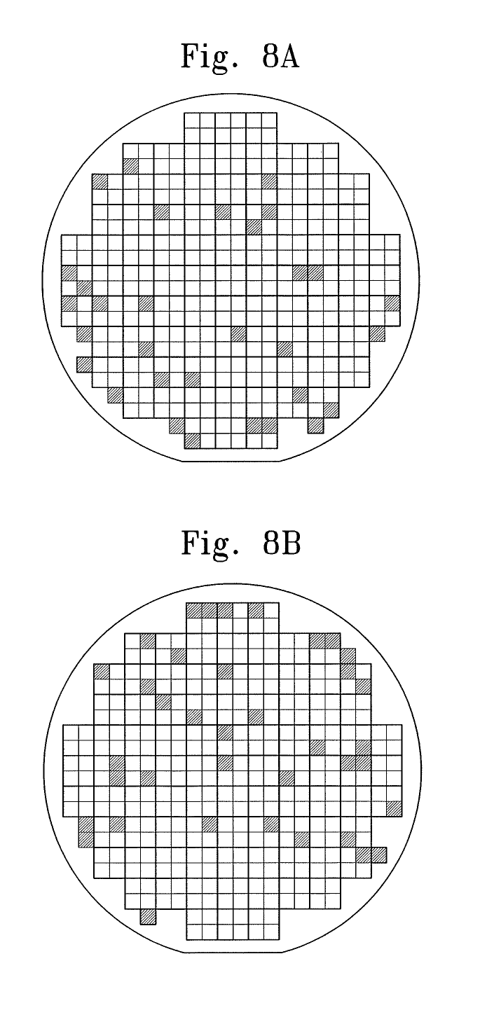

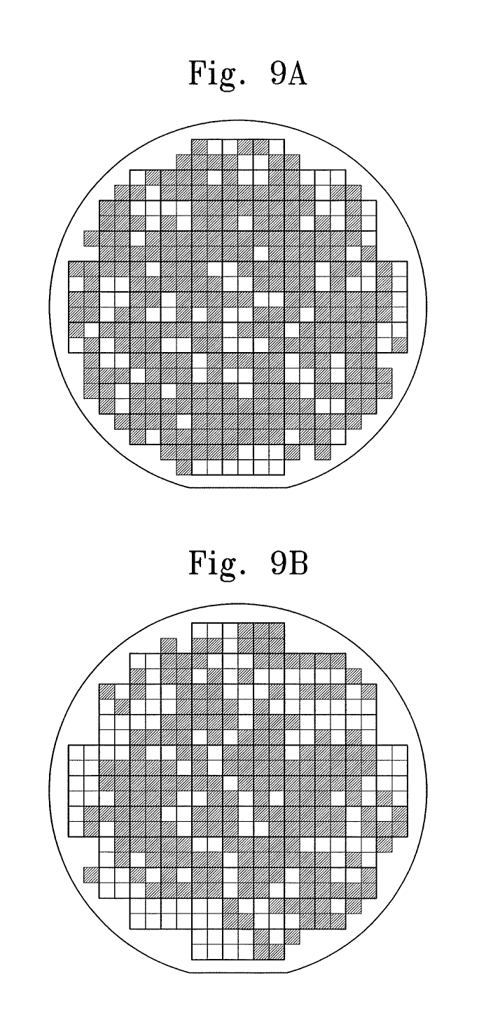

FIGS. 8A and 8B schematically depict images illustrating yields of wafers on which semiconductor devices were fabricated by a method according to example embodiments, and FIGS. 9A and 9B schematically depict images illustrating yields of wafers on which semiconductor devices were fabricated by a conventional method. In FIGS. 8A, 8B, 9A, and 9B, shaded regions depict failed chips.

As described with reference to FIGS. 1 through 4, the top surfaces of the first and second layers were polished to expose the top surface of the insulating layer after the formation of the lower structure and the first and second layers. The first layer may include titanium/titanium nitride, and the second layer may include tungsten.

To provide the wafers depicted in FIGS. 8A and 8B, the first and second layers were cleaned using a cleaning solution containing hydrogen peroxide, sulfuric acid, and ammonium salt, and then subsequent processes were performed to form semiconductor devices. The ammonium salt was at least one of ammonium phosphate, ammonium sulfate, ammonium nitrate, ammonium borate, ammonium persulfate, ammonium citrate, ammonium oxalate, ammonium formate, ammonium carbonate.

To provide the wafers depicted in FIGS. 9A and 9B, the first and second layers were cleaned using a cleaning solution containing hydrofluoric acid (HF) and ammonium hydroxide (NH₄OH) and then subsequent processes were performed to form semiconductor devices.

A yield of the semiconductor devices was about 88.45-90.03% on the wafers of FIGS. 8A and 8B and was about 60.63-62.73% on the wafers of FIGS. 9A and 9B. These results are believed to be due to the fact that the metallic particles and the polishing by-product remained more on the wafer of FIGS. 9A and 9B than on the wafer of FIGS. 8A and 8B.

From the above results, it is shown that the use of the cleaning solution according to example embodiments may enables a reduction in a failure of the semiconductor device caused by the metallic particles and the polishing by-product.

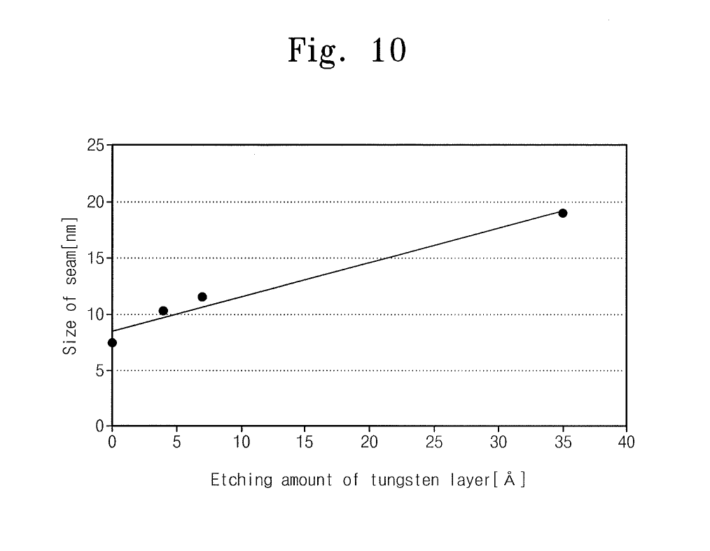

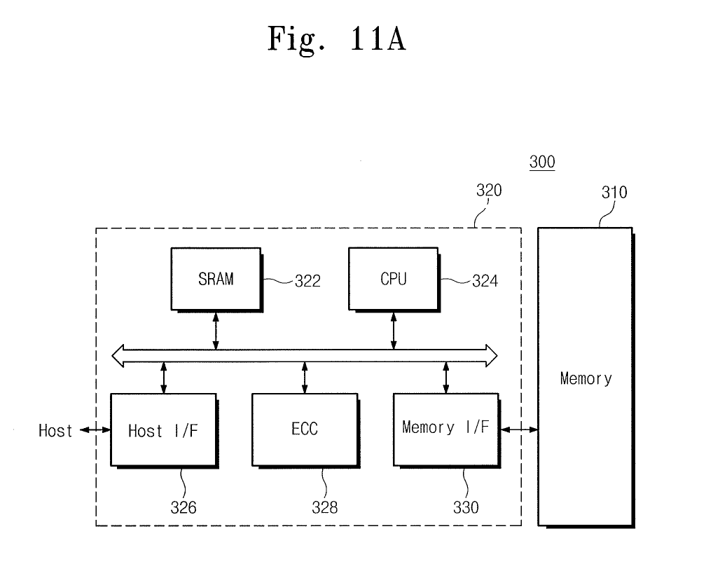

FIG. 10 is a graph showing a relationship between an etching amount of a tungsten layer and a size of void or seam formed in the tungsten layer.

As described in FIGS. 1 through 4, the top surfaces of the titanium/titanium nitride layer and the tungsten layer were polished to expose the top surface of the insulating layer. The polished surfaces of the titanium/titanium nitride layer and the tungsten layer were cleaned using a cleaning solution containing sulfuric acid, hydrogen peroxide, and ammonium salt. The ammonium salt was at least one of ammonium phosphate, ammonium sulfate, ammonium nitrate, ammonium borate, ammonium persulfate, ammonium citrate, ammonium oxalate, ammonium formate, ammonium carbonate.

In FIG. 10, an etching amount, in angstroms, of the tungsten layer is depicted by the x-axis, and a size, in nm, of a seam in the tungsten layer is depicted by the y-axis.

Referring to FIG. 10, with the use of the cleaning solution, an etch rate of the tungsten layer was greater than that of the titanium/titanium nitride layer, and thus, the top surface of the tungsten layer was more etched during the cleaning process, compared with the titanium/titanium nitride layer. As such, the more the top surface of the tungsten layer is etched, the larger the size of the seam in the tungsten layer.

According to example embodiments, for this reason, it may be preferred that the cleaning solution is prepared in such a way that a ratio in etch rate of the titanium/titanium nitride layer to the tungsten layer ranges from about 1 to about 100 or from about 1 to about 20.

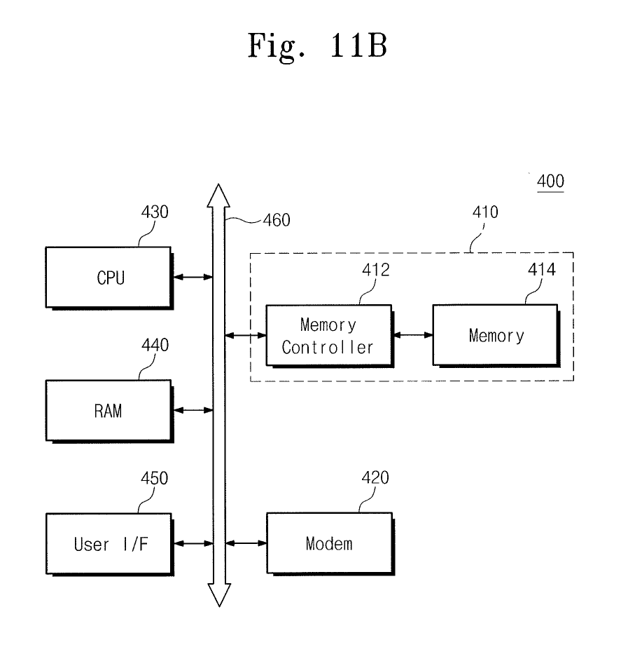

FIG. 11A is a block diagram illustrating a memory card including a semiconductor device according to the example embodiments.

Referring to FIG. 11A, a semiconductor device according to exemplary embodiments may be applied to form a memory card 300. The memory card 300 may include a memory controller 320 to control a data exchange between a host and a memory device 310. A static random access memory 322 may be used as an operation memory of a central processing unit 324. A host interface 326 may include at least one data exchange protocol of the host connected to the memory card 300. An error correction code 328 may detect and correct at least one error that may be included in data read from the memory device 310. A memory interface 330 can interface with the memory device 310. The central processing unit 324 can control data exchange of the memory controller 320 with, for example, the memory device 310.

The memory device 310 in the memory card 300 may include the semiconductor device according to the exemplary embodiments. Accordingly, it may be possible to prevent electrical failure caused by the metallic particles and the polishing by-product, which may enable electric reliability of the memory device 310 to be improved.

FIG. 11B is a block diagram illustrating an information processing system including a semiconductor device according to the example embodiments.

Referring to FIG. 11B, an information processing system 400 may include a semiconductor device according to exemplary embodiments. The information processing system 400 may include a mobile device or a computer. As an illustration, the information processing system 400 may include the memory system 410, a modem 420, a central processing unit (CPU) 430, a random access memory (RAM) 440, and a user interface 450 that are electrically connected to a system bus 460. The memory system 410 may store data processed by the central processing unit (CPU) 430 and data inputted from the outside (e.g., via the user interface 450 and/or the modem 420). The memory system 410 may include a memory 412 and a memory controller 414. The memory system 410 may be the same as the memory card 300 described with reference to FIG. 11A. The information processing system 400 may be provided as a memory card, a solid state disk, a camera image sensor and an application chip set. For example, the memory system 410 may be a solid state disk (SSD). The information processing system 400 may stably and reliably store data in the memory system 410.

According to example embodiments, it may be possible to remove effectively metallic particles and a by-product of a polishing process, which may result from a metal process. As a result, the semiconductor device may have improved electric reliability.

By way of summation and review, as the result of the decrease in the pattern interval in semiconductor devices, technical issues, such as the presence of metallic particles and polishing by-products on metal patterns may occur more often.

Embodiments provide a semiconductor device fabricating method in which the metallic particles and polishing by-products may be removed.

Example embodiments have been disclosed herein, and although specific terms are employed, they are used and are to be interpreted in a generic and descriptive sense only and not for purpose of limitation. Accordingly, it will be understood by those of skill in the art that various changes in form and details may be made without departing from the spirit and scope thereof as set forth in the following claims.

What is claimed is:

1. A method of fabricating a semiconductor device, the method comprising:
forming a first layer including a first metal;
forming a second layer including a second metal, the second layer being adjacent to the first layer;
polishing top surfaces of the first and second layers; and
cleaning the first and second layers using a cleaning solution,
wherein the cleaning solution includes an etching solution etching the first and second layers and an inhibitor suppressing the second layer from being over etched.

2. The method as claimed in claim 1, wherein:
the etching solution includes at least one of sulfuric acid, phosphoric acid, or hydrogen peroxide, and
the inhibitor includes a nitrogen compound.

3. The method as claimed in claim 2, wherein the nitrogen compound includes at least one of ammonium phosphate, ammonium sulfate, ammonium nitrate, ammonium borate, ammonium persulfate, ammonium citrate, ammonium oxalate, ammonium formate, ammonium carbonate, 2-(N,N-diethylamino) ethyl methacrylate, 2-(N,N-dimethylamino) ethyl acrylate, 2-acryloxyethyltrimethylammonium chloride, 2-methacryloxyethyltrimethylammonium chloride, 4,4′-diamino-3,3-dinitrodiphenyl ether, 4-vinylpyridine, chitin, chitosan, diallyldimethylammonium chloride, methacryloylcholine methyl sulfate N-dodecylmethacrylamide, poly(2-dimethylaminoethyl methacrylate), poly(2-methacryloxyethyltrimethylammonium bromide), poly(2-vinyl-1-methylpyridinium bromide), poly(2-vinylpyridine N-oxide), poly(2-vinylpyridine), poly(3-chloro-2-hydroxypropyl-2-methacryloxyethyldimethyl ammonium chloride), poly(4-aminostyrene), poly(4-vinylpyridine N-oxide), poly(4-vinylpyridine), poly(allylamine), amine terminated poly(allylamine hydrochloride), poly(butadiene/acrylonitrile), poly(diallyldimethylammonium chloride), poly(ethylene glycol) bis 2-aminoethyl), poly(L-lysine hydrobromide), poly(N-methylvinylamine), poly(N-vinylpyrrolidone), poly(N-vinylpyrrolidone/2-dimethylaminoethyl methacrylate) dimethyl sulfate quaternary, poly(vinylamine) hydrochloride, polyaniline, or polyethylenimine.

4. The method as claimed in claim 1, further comprising physically cleaning the first and second layers having the polished top surfaces.

5. The method as claimed in claim 4, wherein the physical cleaning is performed using at least one of a spraying method, an ultrasonic method, or a scrubbing method, in which at least one of diluted hydrofluoric acid, diluted ammonia, or deionized water is used.

6. The method as claimed in claim 1, wherein the cleaning of the first and second layers using the cleaning solution includes spraying the cleaning solution.

7. The method as claimed in claim 1, wherein the cleaning of the first and second layers using the cleaning solution further includes physically cleaning the first and second layers using an ultrasonic wave, the using of the ultrasonic wave being executed simultaneously with the using of the cleaning solution.

8. The method as claimed in claim 1, wherein:
the first layer includes a titanium/titanium nitride layer,
the second layer includes a tungsten layer,
the etching solution includes sulfuric acid and hydrogen peroxide, and
the inhibitor includes at least one of ammonium phosphate, ammonium sulfate, ammonium nitrate, ammonium borate, ammonium persulfate, ammonium citrate, ammonium oxalate, ammonium formate, or ammonium carbonate.

9. The method as claimed in claim 1, wherein the forming of the first and second layers includes:
forming a recess in a lower structure;
forming the first layer on the lower structure in a conformal manner; and
forming the second layer to fill the recess formed with the first layer.

10. The method as claimed in claim 9, wherein the polishing of the top surfaces of the first and second layers exposes a top surface of the lower structure.

11. The method as claimed in claim 9, wherein the cleaning of the first and second layers using a cleaning solution removes polishing by-products produced during the forming of the recess and the polishing of the first and second layers.

12. The method as claimed in claim 1, wherein the cleaning solution is provides an etch rate of the first layer that is equivalent to or higher than an etch rate of the second layer.

13. The method as claimed in claim 12, wherein the cleaning solution provides a ratio of an etch rate of the first layer to an etch rate of the second layer that is from about 1 to about 20.

14. A method of fabricating a semiconductor device, the method comprising:
conformally forming a first layer including a first metal on a lower structure, the lower structure including a recess;
forming a second layer including a second metal on the first layer and filling the recess, the second metal being different from the first metal;
performing polishing to form a resultant surface structure including an exposed top surface of the lower structure and exposed top surfaces of the first layer and the second layer in the recess; and
treating the resultant surface structure with a solution that etches the first layer and the second layer, the solution including an inhibitor that prevents the second layer from being over etched.

15. The method as claimed in claim 14, wherein the solution includes:
at least one of sulfuric acid, phosphoric acid, or hydrogen peroxide, and
the inhibitor includes at least one of ammonium phosphate, ammonium sulfate, ammonium nitrate, ammonium borate, ammonium persulfate, ammonium citrate, ammonium oxalate, ammonium formate, ammonium carbonate, 2-(N,N-diethylamino) ethyl methacrylate, 2-(N,N-dimethylamino) ethyl acrylate, 2-acryloxyethyltrimethylammonium chloride, 2-methacryloxyethyltrimethylammonium chloride, 4,4′-diamino-3,3′-dinitrodiphenyl ether, 4-vinylpyridine, chitin, chitosan, diallyldimethylammonium chloride, methacryloylcholine methyl sulfate N-dodecylmethacrylamide, poly(2-dimethylaminoethyl methacrylate), poly(2-methacryloxyethyltrimethylammonium bromide), poly(2-vinyl-1-methylpyridinium bromide), poly(2-vinylpyridine N-oxide), poly(2-vinylpyridine), poly(3-chloro-2-hydroxypropyl-2-methacryloxyethyldimethyl ammonium chloride), poly(4-aminostyrene), poly(4-vinylpyridine N-oxide), poly(4-vinylpyridine), poly(allylamine), amine terminated poly(allylamine hydrochloride), poly(butadiene/acrylonitrile), poly(diallyldimethylammonium chloride), poly(ethylene glycol) bis 2-aminoethyl), poly(L-lysine hydrobromide), poly(N-methylvinylamine), poly(N-vinylpyrrolidone), poly(N-vinylpyrrolidone/2-dimethylaminoethyl methacrylate) dimethyl sulfate quaternary, poly(vinylamine) hydrochloride, polyaniline, or polyethylenimine.

16. The method as claimed in claim 14, wherein:
the first layer includes titanium or titanium nitride as the first metal,
the second layer includes tungsten as the second metal,
the solution includes sulfuric acid and hydrogen peroxide, and
the inhibitor includes at least one of ammonium phosphate, ammonium sulfate, ammonium nitrate, ammonium borate, ammonium persulfate, ammonium citrate, ammonium oxalate, ammonium formate, or ammonium carbonate.

17. The method as claimed in claim 14, further comprising physically cleaning the resultant surface structure using at least one of a spraying method, an ultrasonic method, or a scrubbing method, wherein:
physically cleaning of the resultant surface structure is carried out using at least one of diluted hydrofluoric acid, diluted ammonia, or deionized water, and
physically cleaning the resultant surface structure is carried out in at least one of before, during, or after the cleaning of the resultant structure using the cleaning solution.

18. The method as claimed in claim 14, wherein the solution provides an etch rate of the first layer that is equivalent to or higher than an etch rate of the second layer.

19. The method as claimed in claim 18, wherein the solution provides a ratio of an etch rate of the first layer to an etch rate of the second layer that is from about 1 to about 20.
